(19) United States
(12) Patent Application Publication
(10) Pub. No.: US 2026/0043831 A1
(43) Pub. Date: Feb. 12, 2026

(54) REMOVABLE PROBE CARD

(71) Applicant: STAR TECHNOLOGIES, INC., HSINCHU CITY (TW)

(72) Inventors: Choon Leong LOU, HSINCHU CITY (TW); Hsiao Ting TSENG, ZHUBEI CITY (TW); Chung LO, ZHUBEI CITY (TW)

(21) Appl. No.: 18/944,616

(22) Filed: Nov. 12, 2024

(30) Foreign Application Priority Data
Aug. 6, 2024 (TW) 113208427

(51) Int. Cl. G01R 1/073

(52) U.S. Cl. CPC G01R 1/07342

(57) ABSTRACT

The present disclosure provides a removable probe card including a circuit substrate, a single-layer substrate, multiple probes and multiple conductive traces. The circuit substrate includes multiple conductive pads. The single-layer substrate is disposed on the circuit substrate and exposes the conductive pads of the circuit substrate. A first surface of the single-layer substrate has a probe area and a trace area, and the probe area is surrounded by the trace area. The probes are disposed in the probe area on the single-layer substrate. The conductive traces are disposed in the trace area on the single-layer substrate, do not pass through a body of the single-layer substrate, and are configured to electrically connect the probes to the conductive pads, respectively.

### CROSS REFERENCE TO RELATED APPLICATION

This application claims the benefit of Taiwan Patent Application No. 113208427 (of which the priority date is Aug. 6, 2024), and the subject matter of which is incorporated herein by reference.

### TECHNICAL FIELD

The present disclosure relates to a removable probe card, and more particularly a removable probe card formed by a single-layer substrate.

### DESCRIPTION OF THE PRIOR ART

During the manufacturing process of an integrated circuit, electrical testing is a critical step to ensure that a device is functional. However, as the costs required for probe cards used during a testing process are ever-increasing with continuous miniaturization of electronic elements, then the costs of the electronic elements are also increased.

During the electrical testing, contacts of a test apparatus and distances therebetween are larger, dimensions of a device under test are smaller, and distances between contacts of the device under test are also smaller. An intermediate interface is required between the test apparatus and the device under test to connect the contacts of the test apparatus to the contacts of the device under test. For example, a probe card is used to convert the contacts of the test apparatus to the contacts of the device under test. Such probe card needs to include a substrate (for example, a space converter). The substrate has electrical contacts with larger distances on the side of the test apparatus and electrical contacts with smaller distances on the side of the device under test, accordingly converting the contacts having larger distances of the test apparatus to the contacts having smaller distances of the device under test so as to readily connect to a probe. Then, measurement is made via the electrical contacts between the probe and the device under test.

The probe, once being in contact with the device under test, performs testing, and a test signal is transmitted between the test object and the test apparatus via the substrate. For example, an electrical signal measured by the probe at the device under test is transmitted via the substrate to the test apparatus, and then a test signal is transmitted to the test apparatus via a circuit for further analysis. In general, a substrate of a probe card is a multi-layer substrate, and it is a space conversion unit made according to current multi-layer organic (MLO) or multi-layer ceramics (MLC) techniques. However, production costs of such multi-layer substrate are rather high, and this poses a disadvantage on costs of the probe card. Secondly, dimensions of a removable probe are smaller, and for testing requirements demanding higher leakage current scales, for example, in the pico scale or even the femto scale (10⁻¹² to 10⁻¹⁵ A), the technical solution adopting the multi-layer substrate technique to transmit a signal from the side of the device under test to the side of the test apparatus is unable to fulfill the requirement of low leakage current. Therefore, there is a need for a solution in the present field to overcome the drawings of the prior art.

The details of the “prior art” above describe merely background techniques, and is not to be construed as description for the subject matter of the present disclosure or the prior art of the present disclosure. In addition, the details of the “prior art” above are not to be considered as any part of the present disclosure.

### SUMMARY OF THE PRESENT DISCLOSURE

In view of the above, to overcome the issues of costs and leakage current of probe cards of the prior art, it is an object of the present disclosure to provide a removable probe card.

A removable probe card is provided according to an embodiment of the present disclosure. The removable probe card includes a circuit substrate, a single-layer substrate, multiple probes and multiple conductive traces. The circuit substrate includes multiple conductive pads. The single-layer substrate is disposed on the circuit substrate and exposes the conductive pads of the circuit substrate. A first surface of the single-layer substrate has a probe area and a trace area, wherein the probe area is surrounded by the trace area. The probes are disposed in the probe area on the single-layer substrate. The conductive traces are disposed in the trace area on the single-layer substrate, do not pass through a body of the single-layer substrate, and are configured to electrically connect the probes to the conductive pads, respectively.

On the basis of the removable card provided according to the present disclosure, the single-layer substrate is included to lower production costs of the removable probe card. Moreover, since the conductive traces do not pass through the body of the single-layer substrate, leakage current can be reduced.

The technical features and advantages of the present disclosure are in general comprehensively given in the description above, so as to enable better understanding of the present disclosure as details given in the description below. The other technical features and advantages forming the subject matter of the claims of present disclosure are to be given in the description below. A person skilled in the art of the present disclosure should understand that, it would be easy to implement objects same as those of present disclosure by modifications or designs of other structures or processes on the basis of the concept and specific embodiments disclosed in the description below. Moreover, a person skilled in the art should understand that such equivalent arrangements are to be encompassed within the spirit and scope of the present disclosure as defined by the appended claims.

### BRIEF DESCRIPTION OF THE DRAWINGS

With reference to the embodiments, claims and the accompanying drawings, the disclosure of the present disclosure can be better understood. The same element symbols and numerals in the drawings represent the same elements.

FIG. 1 is a schematic diagram of a test system according to some embodiments of the present disclosure.

FIG. 2 is a schematic diagram of a motherboard according to some embodiments of the present disclosure.

FIG. 3 is a cross-sectional schematic diagram of a removable probe card according to some embodiments of the present disclosure.

FIG. 4 is a top schematic diagram of a removable probe card according to some embodiments of the present disclosure.

FIG. 5 is a top schematic diagram of a removable probe card according to other embodiments of the present disclosure.

### DETAILED DESCRIPTION OF THE EMBODIMENTS

The description of the present disclosure below is accompanied by the drawings forming a part of the description to illustrate the embodiments of the present disclosure. However, it should be noted that the present disclosure is limited to these embodiments. Moreover, the embodiments below can be appropriately integrated into another embodiment.

The terms “an embodiment”, “embodiments”, “exemplary embodiment”, “other embodiment(s)” and “another embodiment” mean that the embodiments described in the present disclosure can include specific features, structures or characteristics; however, it should be noted that not every embodiment needs to include such specific features, structures or characteristics. In addition, the expression “in/of the embodiment” repeatedly used does not necessarily refer to the same embodiment, but may also be the same embodiment.

To fully understand the present disclosure, steps and structures are described in detail below. It is obvious that the implementation of the present disclosure does not limit specific details generally known to a person skilled in the art. Further, generally known structures and steps are not described in detail to prevent unnecessary limitations to the present disclosure. The preferred embodiments of the present disclosure are described in detail below. However, apart from the detailed description, the present disclosure can also be extensively applied in other embodiments. The scope of the present disclosure is not limited to the contents given in the detailed description, but is to be defined and accorded with the appended claims.

It should be understood that the disclosure below provides various embodiments or implementation examples for implementing numerous different features of the present disclosure. Specific embodiments or implementation examples of components and arrangements are set forth below to simplify the present disclosure. It should be noted that such details are exemplary and are not to be intended to be restrictive. For example, a size of an element is not limited to a disclosed range or value, but can depend on an expected property of a manufacturing condition and/or a device. Moreover, in the description below, a first feature formed “on” or “above/over” a second feature may also include an embodiment in which the first feature and the second feature are formed in a direct contact manner, and may include an embodiment in which an additional feature is formed between the first feature and the second feature in a way that the first feature and the second feature may not be in direct contact. For simplicity and clarity, various features may be depicted according to different ratios. In the accompanying drawings, some layers/features are omitted for the sake of simplicity.

Moreover, for better illustration, terms of relative spatial relations such as “beneath”, “below”, “lower”, “above” and “upper” may be used to describe a relation of one element or feature relative to another (other) element(s) or feature(s). Such terms of relative spatial relations are intended to cover different orientations of the element during the use or operation in addition to the orientation depicted in the drawings. An apparatus may be orientated otherwise (rotated by 90 degrees or having another orientation) and the descriptive terms of the relative spatial relations used in the literature may also be similarly and correspondingly interpreted.

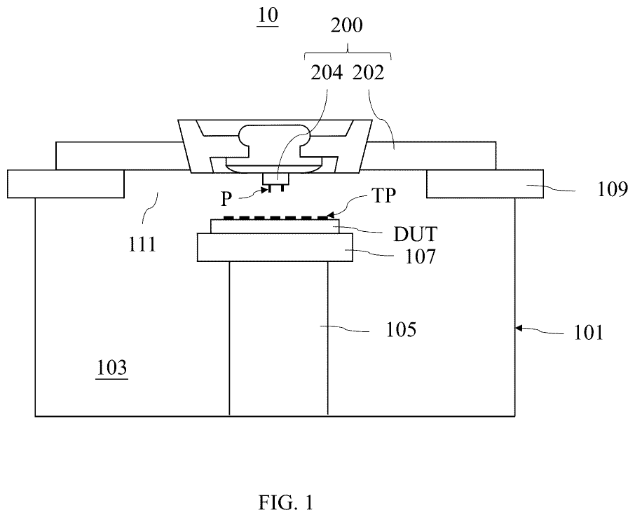

FIG. 1 shows a schematic diagram of a test system 10 according to some embodiments of the present disclosure. The test system 10 is configured to test a device under test DUT. In some embodiments, the device under test DUT is an electronic device having multiple contacts TP. In some embodiments, the device under test DUT is an integrated circuit on a die or a wafer-level integrated circuit. However, the present disclosure is not limited to the examples above, and various electronic elements capable of transmitting electrical signals can be the device under test DUT described in the present disclosure.

The test system 10 includes a housing 101, a three-dimensional carrier 105, a bearing seat 107, a support 109 and a test device 200. The housing 101 defines a test space 103. When the test system 10 performs the testing, the device under test DUT is placed in the test space 103 for testing.

The three-dimensional carrier 105 and the bearing seat 107 are disposed in the test space 103. The bearing seat 107 is configured to carry the device under test DUT, and the three-dimensional carrier 105 is configured to control the position of the bearing seat 107 in the test space 103. That is, the device under test DUT can be moved to a desired position via the control of the three-dimensional carrier 105.

The support 109 is disposed on the housing 101, and the support 109 forms an opening 111 on the housing 101. When the test system 10 performs the testing, the test device 200 is disposed on the support 109, and the test device 200 approaches and comes into contact with the device under test DUT through the opening 111. In some embodiments, when the test system 10 performs the testing, the test device 200 seals the opening 111 such that the test space 103 is formed as an enclosed space.

The test device 200 includes a motherboard 202 and a daughterboard 204. The daughterboard 204 can be disposed on the motherboard 202, and is designed to be removable. The daughterboard 204 includes multiple probes P configured to come into contact with the contacts TP on the device under test DUT during execution of testing so as to transmit electrical signals. In some embodiments, the daughterboard 204 is a removable probe card. For better understanding, the daughterboard 204 is described as a removable probe card 204 below in the present disclosure.

The test system 10 is configured to test multiple different devices under test DUT. It should be noted that the different devices under test DUT have differently configured contacts TP. When the test system 10 needs to test different devices under test DUT, the removable probe card 204 of the test device 200 can be replaced instead of replacing the entire test device 200. The design of the motherboard 202 and the removable probe card 204 achieves the following advantages. First of all, the production costs of the motherboard 202 of the test device 200 can be lowered. Secondly, for cleaning and maintenance of the probes P on the removable probe card 204, operations can be performed only on the removable probe card 204 having a smaller volume. Thirdly, calibration needs to be performed on the removable probe card 204 before and after testing, and if the removable probe card 204 is removed and the calibration is then performed, the time for performing testing using other removable probe cards 204 will not be occupied.

In some embodiments, the test device 200 is connected to an external test apparatus (not shown). The external test apparatus is configured to transmit and/or receive electrical signals from/to the device under test DUT via the test device 200. In some embodiments, the external test apparatus is further configured to analyze the performance of the device under test DUT according to the received electrical signals.

In some embodiments, the test system 10 further includes a temperature control element (not shown) configured to control the temperature of the test space 103 and/or the device under test DUT.

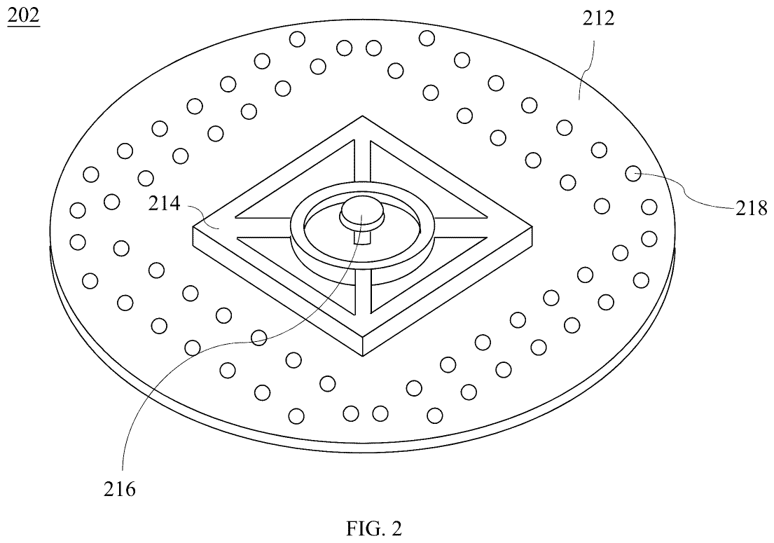

FIG. 2 shows a schematic diagram of the motherboard 202 according to some embodiments of the present disclosure. The motherboard 202 includes a basic circuit board 212, a fixing base 214, a probe card carrier 216, and multiple conductive contacts 218. The fixing base 214 is disposed on the basic circuit board 212. The probe card carrier 216 is disposed in the fixing base 214 and is configured to receive the removable probe card 204. The fixing base 214 and the probe card carrier 216 are configured to jointly fix the removable probe card 204 on the motherboard 202. The conductive contacts 218 are disposed on an outer periphery of the basic circuit board 212, and substantially surround the fixing base 214. The conductive contacts 218 are configured to electrically connect the external test apparatus and the removable probe card 204.

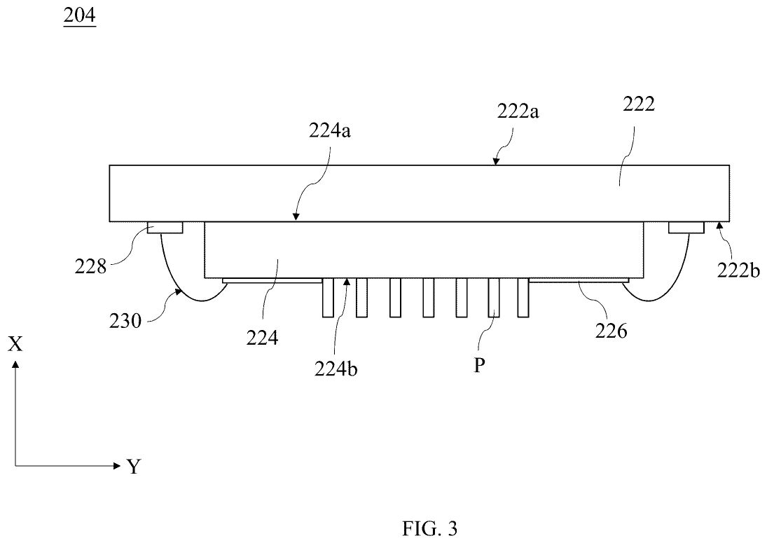

FIG. 3 shows a cross-sectional schematic diagram of the removable probe card 204 according to some embodiments of the present disclosure. To facilitate understanding, the cross-sectional schematic diagram in FIG. 3 uses a plane mutually defined by the X direction and the Y direction as a cross section. The removable probe card 204 includes a circuit substrate 222, a single-layer substrate 224, multiple probes P and multiple conductive traces 226.

The circuit substrate 222 has a surface 222a and a surface 222b opposite to each other. When the removable probe card 204 is installed on the probe card carrier 216, the surface 222a faces the probe card carrier 216. The single-layer substrate 224 is disposed on the surface 222b of the circuit substrate 222. The single-layer substrate 224 has a surface 224a and a surface 224b opposite to each other, and the surface 224a is in contact with the surface 222b of the circuit substrate 222.

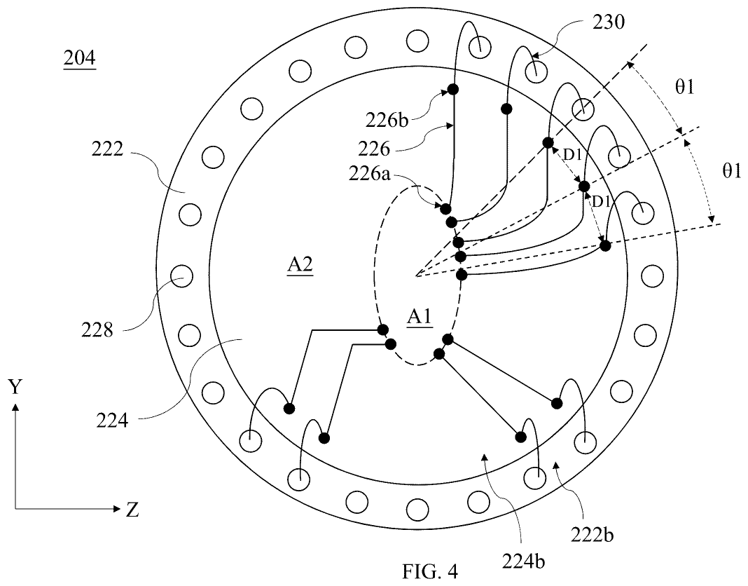

The circuit substrate 222 includes multiple conductive pads 228 disposed on an outer periphery of the surface 222b of the circuit substrate 222. The single-layer substrate 224 exposes the conductive pads 228. In other words, the single-layer substrate 224 and the conductive pads 228 do not overlap. Refer to FIG. 4. FIG. 4 shows a top schematic diagram of the removable probe card 204 according to some embodiments of the present disclosure. A perspective of the top schematic diagram in FIG. 4 is perpendicular to a plane mutually defined by the Y direction and the Z direction. The surface 224b of the single-layer substrate 224 has a probe area A1 and a trace area A2, and the probe area A1 is surrounded by the trace area A2.

The probes P are disposed in the probe area A1 on the surface 224b of the single-layer substrate 224. In some embodiments, the probes P are vertical probes. In some embodiments, the probes P are microelectromechanical system (MEMS) probes. It should be understood that the arrangement of the probes P shown in the drawings of the present disclosure is merely illustrative and is not to be construed as limitations to the present disclosure. The numbers and arrangements of the probes P can be configured according to requirements of the device under test Dut.

The conductive traces 226 are disposed in the trace area A2 on the single-layer substrate 224, and are configured to electrically connect the probes P to the conductive pads 228. In some embodiments, one probe P is electrically connected to one conductive pad 228 via one conductive trace 226. However, the present disclosure is not limited to the example above; corresponding relationships of different numbers of probes P, conductive traces 226 and conductive pads 228 are within the contemplated scope of the present disclosure.

In some embodiments, the conductive traces 226 are electrically connected to the conductive pads 228 via bonding wires 230. In other embodiments, the conductive traces 226 can be electrically connected to the conductive pads 228 by means of other appropriate connections.

It should be noted that the conductive traces 226 on the single-layer substrate 224 are disposed only on the surface 224b of the single-layer substrate 224. The conductive traces 226 do not pass through a body of the single-layer substrate 224. In other words, there are no paths for electrical connection inside the single-layer substrate 224.

In some embodiments, the single-layer substrate 224 is a single-layer ceramic substrate and is a monolithic structure. A ceramic substrate has properties of low thermal expansion, low resistance and high strength, hence providing higher stabilities during the testing. However, a ceramic substrate in a multi-layer structure is applied in some techniques of the prior art. During the manufacturing of the ceramic substrate in the multi-layer structure, not only the temperature of a casting process has to be precisely controlled, but also a circuit layout of each layer of the ceramic substrate needs to be designed to match different devices under test. Furthermore, two circuit layouts in adjacent layers have to match with each so that the connections between the adjacent layers can be formed. The above reasons results that the production costs and complexities of probe cards are significant increased. Moreover, complicated circuit layouts can further produce issues such as parasitic capacitance, interference and leakage current.

Compared to the prior art above, the single-layer substrate 224 of the present disclosure uses only one layer of ceramic as a substrate. The single-layer substrate 224 has a simpler design in circuit layouts, lower production costs and better performance in suppressing leakage current compared to those of a multi-layer circuit board.

The probe area A1 is defined by an ellipsoid in a dotted line in FIG. 4 and is substantially located at a center of the surface 224b. The trace area A2 is the remaining area apart from the probe area A1 on the surface 224b, and the trace area A2 surrounds the probe area A1. In some embodiments, an area of the trace area A2 is greater than an area of the probe area A1.

The probes P are disposed in the probe area A1 (the probes P are omitted from FIG. 4 for the sake of keeping the drawing simple). The conductive traces 226 are disposed in the trace area A2. It should be understood that the dotted line of the ellipsoid in FIG. 4 is an imaginary line and is not a physical structure on the single-layer substrate 224. In some embodiments, an area in which the probes P are disposed is the probe area A1.

Each of the conductive traces 226 includes a first end 226a coupled to the probe P and a second end 226b coupled to the conductive pad 228. The first end 226a is located at an interface between the probe area A1 and the trace area A2, and the second end 226b is located on an outer periphery of the trace area A2. The outer periphery of the trace area A2 is defined on an edge of the surface 224b of the single-layer substrate 224. The bonding wire 230 is configured to electrically connect the second end 226b to the corresponding conductive pad 228 on the circuit substrate 222.

As described above, since there are not paths for electrical connection inside the single-layer substrate 224, the conductive traces 226 are disposed only on the surface 224b of the single-layer substrate 224. Because only one surface 224b is available for disposing the conductive traces 226, these conductive traces 226 cannot overlap or cross one another.

In some embodiments, the second ends 226b of the conductive traces 226 are evenly distributed on the outer periphery of the trace area A2. In some embodiments, a distance D1 between every two adjacent second ends 226b is equal to one another. In some embodiments, the single-layer substrate 224 is circular, and an included angle θ1 formed by every two adjacent second ends 226b with respect to the center of the single-layer substrate 224 is equal to one another.

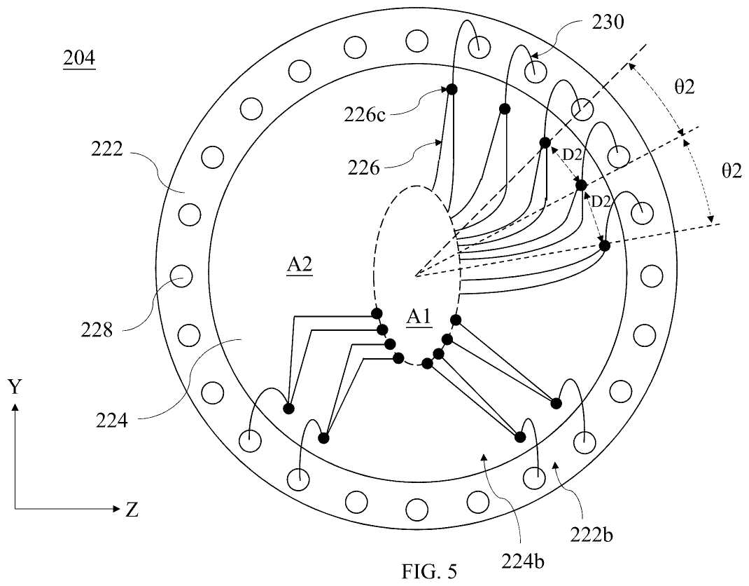

FIG. 5 shows a top schematic diagram of the removable probe card 204 according to other embodiments of the present disclosure. A perspective of the top schematic diagram in FIG. 5 is perpendicular to a plane mutually defined by the Y direction and the Z direction.

The removable probe card 204 in FIG. 5 is similar to the removable probe 204 in FIG. 4. However, in the removable probe card 204 in FIG. 5, the second ends 226b of the multiple conductive traces 226 form a line end group 226c. As shown in FIG. 5, the second ends 226b of every two conductive traces 226 form one line end group 226c. The bonding wire 230 is configured to electrically connect the line end group 226c to the corresponding conductive pad 228 on the circuit substrate 222. It should be understood that different numbers of second ends 226b can also form one line end group 226c. The present disclosure is not limited the line end group 226c formed by two second ends 226b.

In some embodiments, these line end groups 226c are evenly distributed on the outer periphery of the trace area A2. In some embodiments, a distance D2 between every two adjacent line end groups 226c is equal to one another. In some embodiments, the single-layer substrate 224 is circular, and an included angle θ2 formed by every two adjacent line end groups 226c with respect to the center of the single-layer substrate 224 is equal to one another.

In light of the above, the removable probe card of the present disclosure applies a single-layer substrate for disposing probes and conductive traces, hence lowering costs of the removable probe card and at the same time enhancing the ability for suppressing leakage current.

The present disclosure and the advantages thereof are described in detail as above. However, it should be understood that various modifications, replacements and substitutions can be made without departing from the spirit and scope of the present disclosure as defined by the appended claims. For example, various processes above may be implemented by different approaches, and other processes or a combination thereof may be used in substitution for the various processes above.

Moreover, the scope of the present disclosure is not limited to specific embodiments of the processes, machines, manufacturing, substance compositions, means, methods or steps given in the detailed description. A person skilled in the art could understand from disclosure of the present disclosure that existing or future developed processes, machines, manufacturing, substance compositions, means, methods or steps that achieve the same functions or achieve substantially the same results corresponding to those of the embodiments described in the literature can be utilized. Accordingly, such processes, machines, manufacturing, substance compositions, means, methods or steps are to be encompassed within the scope of the appended claims.

What is claimed is:

1. A removable probe card, comprising:
a circuit substrate, comprising a plurality of conductive pads;
a single-layer substrate, disposed on a the circuit substrate and exposing the conductive pads of the circuit substrate, wherein a first surface of the single-layer substrate has a probe area and a trace area, and the probe area is surrounded by the trace area;
a plurality of probes, disposed in the probe area on the single-layer substrate; and
a plurality of conductive traces, disposed in the trace area on the single-layer substrate, not passing through a body of the single-layer substrate, and configured to electrically connect the probes to the conductive pads, respectively.

2. The removable probe card according to claim 1, wherein the single-layer substrate is a single-layer ceramic substrate and is a monolithic structure.

3. The removable probe card according to claim 1, wherein an area of the trace area is greater than an area of the probe area.

4. The removable probe card according to claim 1, wherein the trace area has an outer periphery which is defined on an edge of the first surface.

5. The removable probe card according to claim 4, wherein each of the conductive traces comprises:
a first end, electrically connected to corresponding one of the probes; and
a second end, arranged on the outer periphery of the trace area.

6. The removable probe card according to claim 5, wherein the second ends are evenly distributed at the outer periphery.

7. The removable probe card according to claim 6, wherein a distance between two adjacent second ends is equal to one another.

8. The removable probe card according to claim 5, further comprising:
a plurality of line end groups, connected to the second ends of the conductive traces, respectively.

9. The removable probe card according to claim 5, wherein the second end is electrically connected to corresponding one of the conductive pads via a bonding wire.
